(19) United States
(12) Patent Application Publication
(10) Pub. No.: US 2013/0221320 A1
(43) Pub. Date: Aug. 29, 2013

(54) LED WITH EMBEDDED DOPED CURRENT BLOCKING LAYER

(71) Applicants: Zhen-Yu Li, Zhuqi Township (TW); Hsing-Kuo Hsia, Jhubei City (TW); Hao-Chung Kuo, Tsu-Bai City (TW)

(72) Inventors: Zhen-Yu Li, Zhuqi Township (TW); Hsing-Kuo Hsia, Jhubei City (TW); Hao-Chung Kuo, Tsu-Bai City (TW)

(73) Assignee: TSMC Solid State Lighting Ltd., HsinChu (TW)

(21) Appl. No.: 13/405,906

(22) Filed: Feb. 27, 2012

(51) Int. Cl. H01L 33/04

(52) U.S. Cl. 257/9; 438/45; 257/E33.008

(57) ABSTRACT

The present disclosure involves an apparatus. The apparatus includes a photonic die structure that includes a plurality of layers. A current blocking layer is embedded in one of the plurality of layers. The current blocking layer is a doped layer. The present disclosure also involves a method of fabricating a light-emitting diode (LED). As a part of the method, an LED is provided. The LED includes a plurality of layers. A patterned mask is then formed over the LED. The patterned mask contains an opening. A dopant is introduced through the opening to a layer of the LED through either an ion implantation process or a thermal diffusion process. As a result of the dopant being introduced, a doped current blocking component is formed to be embedded within the layer of the LED.

### TECHNICAL FIELD

The present disclosure relates generally to light-emitting devices, and more particularly, to a light-emitting diode (LED) having an embedded current blocking layer.

### BACKGROUND

An LED device or an LED, as used herein, is a semiconductor light source for generating a light at a specified wavelength or a range of wavelengths. LEDs have increasingly gained popularity due to favorable characteristics such as small device size, long lifetime, efficient energy consumption, and good durability and reliability. In recent years, LEDs have been deployed in various applications, including indicators, light sensors, traffic lights, broadband data transmission, and illumination devices. LEDs emit light when a voltage is applied.

LEDs may be made by growing a plurality of light-emitting structures on a growth substrate. The light-emitting structures along with the underlying growth substrate are separated into individual LED dies. At some point before or after the separation, electrodes or conductive pads are added to the each of the LED dies to allow the conduction of electricity across the structure. The light-emitting structure and the wafer on which the light-emitting structure is formed are referred to herein as an epi wafer. LED dies are then packaged by adding a package substrate, optional phosphor material, and optics such as lens and reflectors to become an optical emitter.

LEDs typically include a current blocking layer. Traditionally, the formation of the current blocking layer involves depositing a dielectric material and patterning the dielectric material. However, these processes not only require extra fabrication tools but also may lead to degraded device performance, for example worse current leakage performance due to uneven device surfaces.

Therefore, while existing methods of manufacturing the LEDs have been generally adequate for their intended purposes, they have not been entirely satisfactory in every aspect. A better current blocking layer for LEDs continues to be sought.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1-11 are diagrammatic fragmentary cross cross-sectional side views of example LED structures according to various aspects of the present disclosure.

FIG. 12 is a flowchart illustrating a method of fabricating an LED according to various aspects of the present disclosure.

FIG. 13 is a diagrammatic view of a lighting module that includes the LED of FIGS. 1-11 according to various aspects of the present disclosure.

### DETAILED DESCRIPTION

It is understood that the following disclosure provides many different embodiments, or examples, for implementing different features of various embodiments. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Moreover, the terms “top,” “bottom,” “under,” “over,” and the like are used for convenience and are not meant to limit the scope of embodiments to any particular orientation. Various features may also be arbitrarily drawn in different scales for the sake of simplicity and clarity. In addition, the present disclosure may repeat reference numerals and/or letters in the various examples. This repetition is for the purpose of simplicity and clarity and does not in itself necessarily dictate a relationship between the various embodiments and/or configurations discussed.

When turned on, light-emitting diode (LED) devices may emit radiation such as different colors of light in a visible spectrum, as well as radiation with ultraviolet or infrared wavelengths. Compared to traditional light sources (e.g., incandescent light bulbs), LEDs offer advantages such as smaller size, lower energy consumption, longer lifetime, variety of available colors, and greater durability and reliability. These advantages, as well as advancements in LED fabrication technologies that have made LEDs cheaper and more robust, have added to the growing popularity of LEDs in recent years.

Nevertheless, existing LED fabrication technologies may face certain shortcomings. One such shortcoming is that existing LEDs typically have a current blocking layer that is formed by depositing a dielectric material and thereafter patterning the dielectric through a photolithography process. The patterned current blocking layer resides on a layer surface of the LED, thus making the LED layer surface uneven. This surface unevenness may lead to performance issues such as current leakage and/or increase in operation voltage. Furthermore, the photolithography process used to form the current blocking layer for traditional LEDs necessarily involves additional lithography equipment, thereby prolonging fabrication time and increasing fabrication costs.

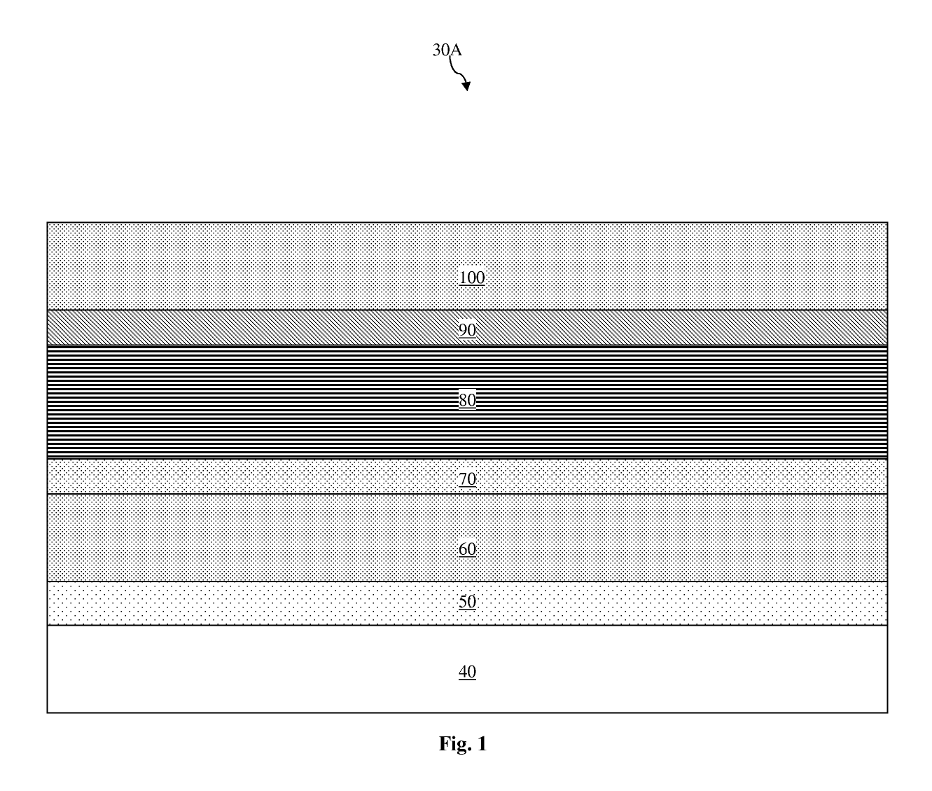

According to various aspects of the present disclosure, described below is a semiconductor photonic device and a method of fabrication thereof that substantially overcomes these issues discussed above by forming an embedded current blocking layer. The photonic device is an LED in the embodiments discussed below. In more detail, FIGS. 1 to 11 are diagrammatic cross-sectional side views of a portion of an LED at various fabrication stages. FIGS. 1 to 11 have been simplified for a better understanding of the inventive concepts of the present disclosure.

Referring to FIG. 1, an LED 30A includes a substrate 40. The substrate 40 is a portion of a wafer. In some embodiments, the substrate 40 includes a sapphire material. The substrate 40 may have a thickness that is in a range from about 200 microns (um) to about 1000 um.

An undoped semiconductor layer 50 is formed over the substrate 40. The undoped semiconductor layer 50 is free of a p-type dopant or an n-type dopant. In some embodiments, the undoped semiconductor layer 50 includes a compound that contains an element from a “III” group (or family) of the periodic table, and another element from a “V” group (or family) of the periodic table. For example, the III group elements may include Boron, Aluminum, Gallium, Indium, and Titanium, and the V group elements may include Nitrogen, Phosphorous, Arsenic, Antimony, and Bismuth. In the illustrated embodiments, the undoped semiconductor layer 50 includes an undoped gallium nitride (GaN) material.

The undoped semiconductor layer 50 serves as a buffer layer (for example, to reduce stress) between the substrate 40 and layers that will be formed over the undoped semiconductor layer 50. To effectively perform its function as a buffer layer, the undoped semiconductor layer 50 has reduced dislocation defects and good lattice structure quality. In certain embodiments, the undoped semiconductor layer 50 has a thickness that is in a range from about 1.5 um to about 3.0 um.

A doped semiconductor layer 60 is formed over the undoped semiconductor layer 50. The doped semiconductor layer 60 is formed by an epitaxial growth process known in the art. In the illustrated embodiments, the doped semiconductor layer 60 is doped with an n-type dopant, for example Carbon (C) or Silicon (Si). In alternative embodiments, the doped semiconductor layer 60 may be doped with a p-type dopant, for example Magnesium (Mg). The doped semiconductor layer 60 includes a III-V group compound, which is gallium nitride compound in the present embodiment. Thus, the doped semiconductor layer 60 may also be referred to as a doped gallium nitride layer. In some embodiments, the doped semiconductor layer 60 has a thickness that is in a range from about 2 um to about 4 um.

A pre-strained layer 70 is formed on the doped semiconductor layer 60. The pre-strained layer 70 may be doped with an n-type dopant such as Silicon. The pre-strained layer 70 may serve to release strain and reduce a quantum-confined Stark effect (QCSE)—describing the effect of an external electric field upon the light absorption spectrum of a quantum well that is formed thereabove (i.e., the MQW layer 80 discussed below). The pre-strained layer 70 may have a thickness in a range from about 30 nm to about 80 nm.

A multiple-quantum well (MQW) layer 80 is formed over the pre-strained layer 70. The MQW layer 80 includes alternating (or periodic) sub-layers of active material, such as gallium nitride and indium gallium nitride (InGaN). For example, the MQW layer 80 may include a number of gallium nitride sub-layers and a number of indium gallium nitride sub-layers, wherein the gallium nitride sub-layers and the indium gallium nitride sub-layers are formed in an alternating or periodic manner. In one embodiment, the MQW layer 80 includes ten sub-layers of gallium nitride and ten sub-layers of indium gallium nitride, where an indium gallium nitride sub-layer is formed on a gallium nitride sub-layer, and another gallium nitride sub-layer is formed on the indium gallium nitride sub-layer, and so on and so forth. Each of the sub-layers within the MQW layer is doped with a different type of conductivity from its adjacent sub-layer. That is, the various sub-layers within the MQW layer are doped in an alternating p-n fashion. The light emission efficiency depends on the number of layers of alternating layers and their thicknesses. In some embodiments, the MQW layer 80 has a thickness in a range from about 90 nanometers (nm) to about 200 nm.

An electron blocking layer 90 may optionally be formed over the MQW layer 80. The electron blocking 90 layer helps confine electron-hole carrier recombination within the MQW layer 80, which may improve quantum efficiency of the MQW layer 80 and reduce radiation in undesired bandwidths. In some embodiments, the electron blocking layer 90 may include a doped aluminum gallium nitride (AlGaN) material, and the dopant includes Magnesium. The electron blocking layer 90 may have a thickness in a range from about 15 nm to about 20 nm.

A doped semiconductor layer 100 is formed over the electron blocking layer 90 (and thus over the MQW layer 80). The doped semiconductor layer 100 is formed by an epitaxial growth process known in the art. In some embodiment, the doped semiconductor layer 100 is doped with a dopant having an opposite (or different) type of conductivity from that of the doped semiconductor layer 60. Thus, in the embodiment where the doped semiconductor layer 60 is doped with an n-type dopant, the doped semiconductor layer 100 is doped with a p-type dopant, and vice versa. The doped semiconductor layer 100 includes a III-V group compound, which is a gallium nitride compound in the illustrated embodiments. Thus, the doped semiconductor layer 100 may also be referred to as a doped gallium nitride layer. In some embodiments, the doped semiconductor layer 100 has a thickness that is in a range from about 150 nm to about 200 nm.

A core portion of the LED 30A is created by the disposition of the MQW layer 80 between the doped layers 60 and 100. When an electrical voltage (or electrical charge) is applied to the doped layers of the LED 30A, the MQW layer 80 emits radiation such as light. The color of the light emitted by the MQW layer 80 corresponds to the wavelength of the radiation. The radiation may be visible, such as blue light, or invisible, such as ultraviolet (UV) light. The wavelength of the light (and hence the color of the light) may be tuned by varying the composition and structure of the materials that make up the MQW layer 80.

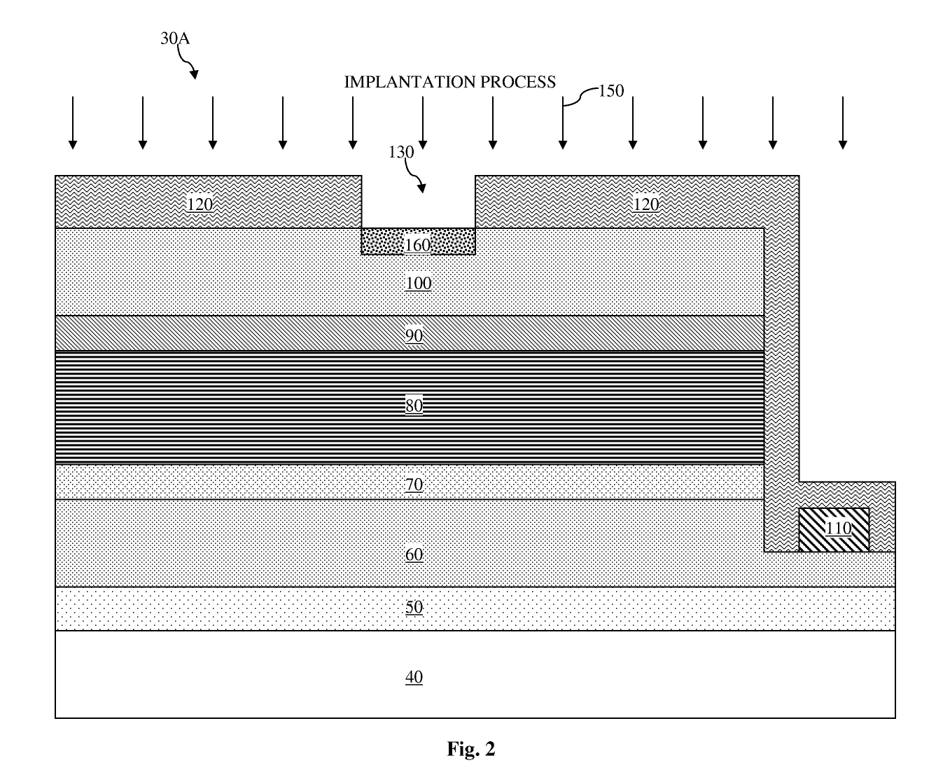

Referring to FIG. 2, portions of the layers 60-100 are etched away so that a part of the doped semiconductor layer 60 is exposed. A metal contact 110 is formed on the surface of the exposed doped semiconductor layer 60. The metal contact 110 is formed by one or more deposition and patterning processes. The metal contact 110 allows electrical access to the doped semiconductor layer 60.

A patterned photoresist layer 120 is formed over the doped semiconductor layer 100. The patterned photoresist layer 120 includes an opening 130 that exposes a part of the doped semiconductor layer 100. An ion implantation process 150 is then performed to the LED 30A. The patterned photoresist layer 120 serves as an implantation mask during the ion implantation process 150. The ion implantation process 150 implants dopant ions into the doped semiconductor layer 100. In some embodiments, the dopant ions include Caesium (Cs), Argon (Ar), Neon (Ne), Krypton (Kr), Nitrogen (N), Aluminum (Al), Oxygen (O), or Boron (B). The dose density may vary from about 1.0×10¹⁰ ions/centimeter² to about 1.0×10¹⁸ ions/centimeter². In some embodiments, the dose density may be in a range from about 1.0×10¹² ions/centimeter² to about 1.0×10¹⁶ ions/centimeter². In some other embodiments, the dose density may be in a range from about 1.0×10¹³ ions/centimeter² to about 1.0×10¹⁷ ions/centimeter². In certain embodiments, an implant depth as a result of the ion implantation process 150 is in a range from about 0 nm to about 200 nm. After the ion implantation process 150 is performed, an annealing process may be performed. In some embodiments, the annealing process may have an annealing temperature less than or equal to about 500 degrees Celsius and an annealing time less than or equal to about 5 minutes.

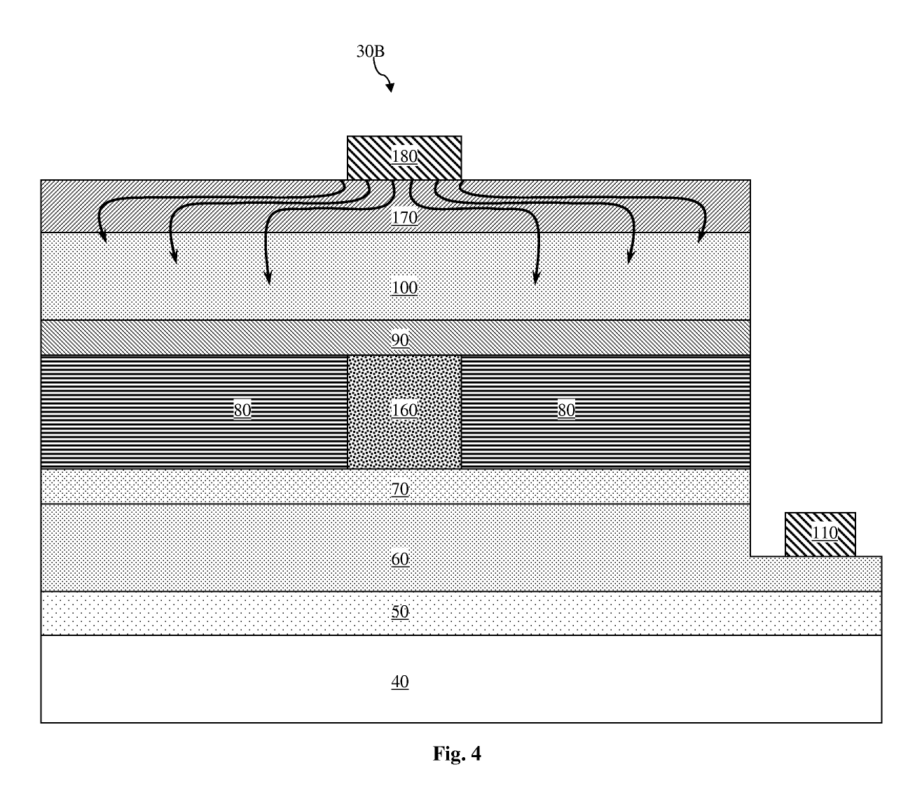

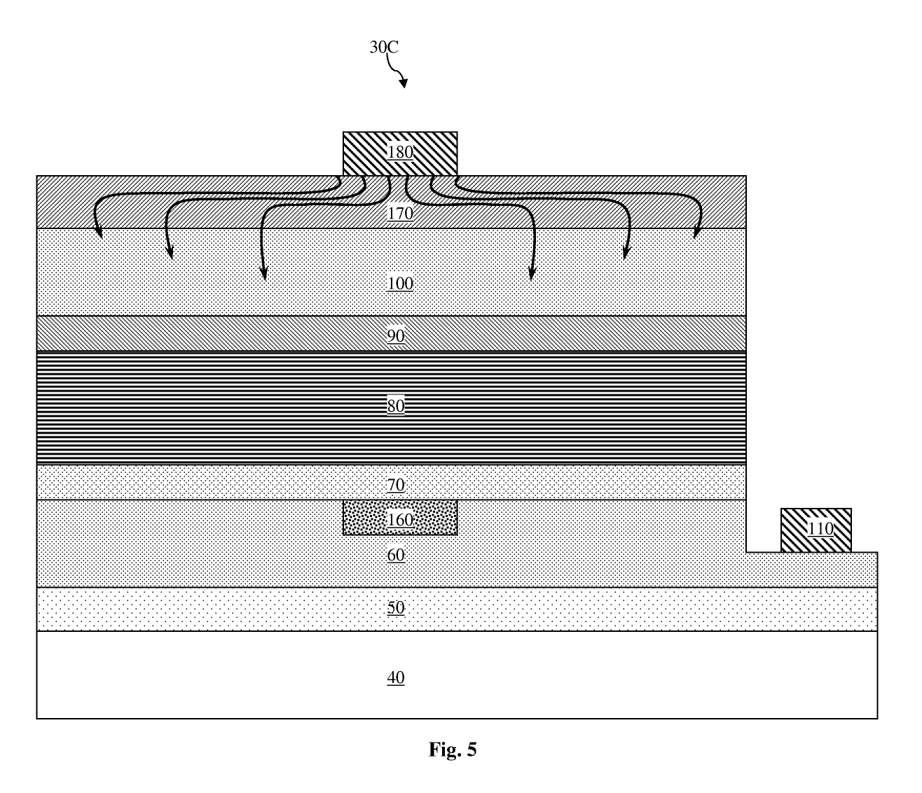

As a result of the ion implantation process 150, a current blocking layer 160 is formed in the doped semiconductor layer 100 below the opening 130. The current blocking layer 160 has a high resistivity. In some embodiments, the resistivity (p) is greater than or equal to about 10⁴ ohms-centimeter. In some alternative embodiments, the implantation energies may be tuned to form a current blocking layer 160 in other layers of the LED 30A, for example in the MQW layer 80, or the doped semiconductor layer 60, or another suitable layer. Some of these alternative embodiments are discussed below with reference to FIGS. 4 and 5.

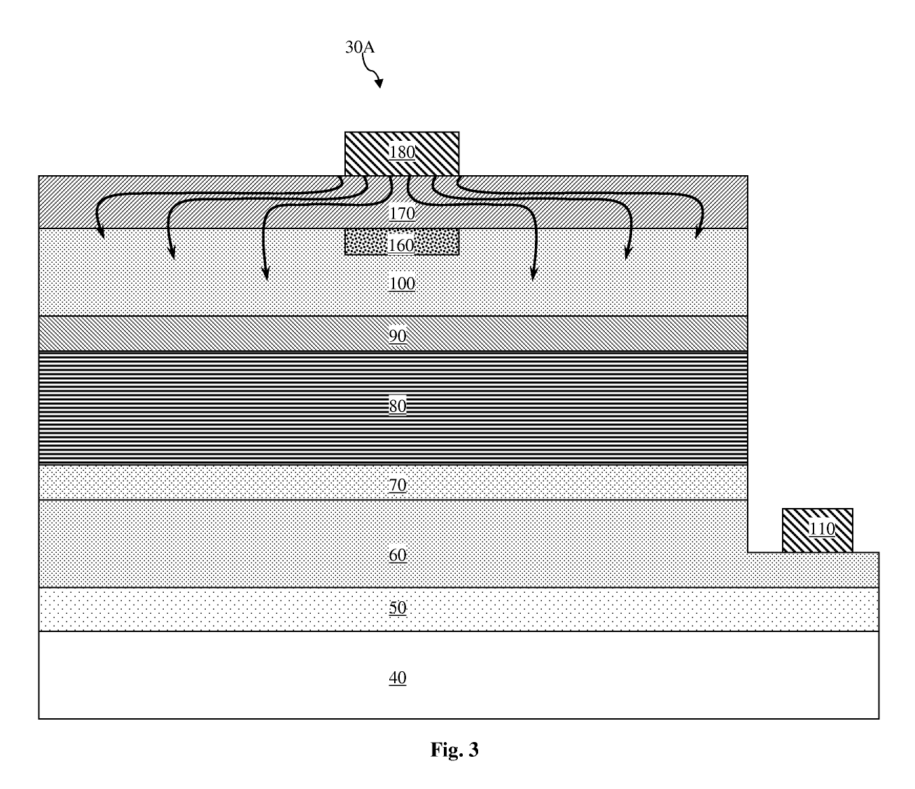

Referring now to FIG. 3, the photoresist layer 120 is removed, for example using a stripping process or an ashing process known in the art. Thereafter, a contact layer 170 is formed over the doped semiconductor layer 100 (and over the current blocking layer 160). In some embodiments, the contact layer 170 includes a conductive and transparent material such as ITO, ZnO, or (AlGa)ZnO. In certain embodiments, the contact layer 170 has a thickness in a range from about 2000 Angstroms to about 3000 Angstroms, a transmission rate greater than about 85%, and a resistivity less than about 5×10⁻⁴ ohms-centimeter.

A metal contact 180 is then formed over the contact layer 170. The metal contact 180 allows electric access to the doped semiconductor layer 100. The metal contact 180 is approximately vertically aligned with the current blocking layer 160. As discussed above, the current blocking layer 160 has a high resistivity and as such diverts current flow away from it. This effect is illustrated by the arrows shown in FIG. 3. In doing so, the current blocking layer 160 can improve the light output power and quantum efficiency of the LED 30A, as it can help increase current flow in the MQW layer 80 of the LED 30A.

Since the current blocking layer 160 is formed by an ion implantation process, it is embedded within a layer of the LED 30A, for example embedded within the doped semiconductor layer 100. As such, unlike conventional LEDs, the formation of the current blocking layer 160 does not lead to an uneven surface for any layers within the LED 30A. The flat surface of the doped semiconductor layer 100 reduces the likelihood of current leakage or other defects or performance degradations for the LED 30A. Furthermore, since the formation of the current blocking layer 160 involves no lithography equipment, the fabrication of the LED 30A can be done faster and at a lower cost than conventional LEDs that do need a lithography process to form its current blocking layer.

In the embodiments discussed above, the current blocking layer 160 is formed by an ion implantation process. In alternative embodiments, however, the current blocking layer 160 may be formed by a suitable thermal diffusion process, which may also involve introducing a dopant such as Caesium, Argon, Neon, Krypton, Nitrogen, Aluminum, Oxygen, or Boron through the opening 130 (FIG. 2) to form a doped current blocking layer. In these embodiments where thermal diffusion is employed to form the doped current blocking layer, the current blocking layer would be formed close to the surface exposed to the diffuser (i.e., the dopant).

FIGS. 4 and 5 are diagrammatic cross-sectional side view of an LED 30B and an LED 30C according to two alternative embodiments, respectively. In these alternative embodiments in FIGS. 4-5, the current blocking layer of the respective LED is formed in different other layers within the LED. For reasons of consistency and clarity, similar components in LEDs 30A-30C are labeled the same. Referring to FIG. 30B, the current blocking layer 160 is formed in the MQW layer 80, rather than in the doped semiconductor layer 100 (e.g., pGaN layer). In spite of what is illustrated in FIG. 4 (which is just an embodiment), the current blocking layer 160 may or may not be formed all the way through the MQW layer 80. For example, the current blocking 160 may be formed only partially in the MQW layer 80. As another example, the current blocking layer 160 may be formed across a part of layer 70 or across a part of layer 80 as well.

As discussed above, the location and depth of the current blocking layer can be achieved by tuning the process parameters (e.g., implantation energy) of the ion implantation process used to form the current blocking layer 160. Referring to FIG. 30C, the current blocking layer 160 is formed in the doped semiconductor layer 60 (e.g., nGaN layer), rather than in the doped semiconductor layer 100 or in the MQW layer 80. As discussed above, this can be achieved by tuning the process parameters of the ion implantation process used to form the current blocking layer 160. Furthermore, a desired depth (or vertical dimension) of the current blocking layer 160 may be achieved by tuning some of the ion implantation process parameters.

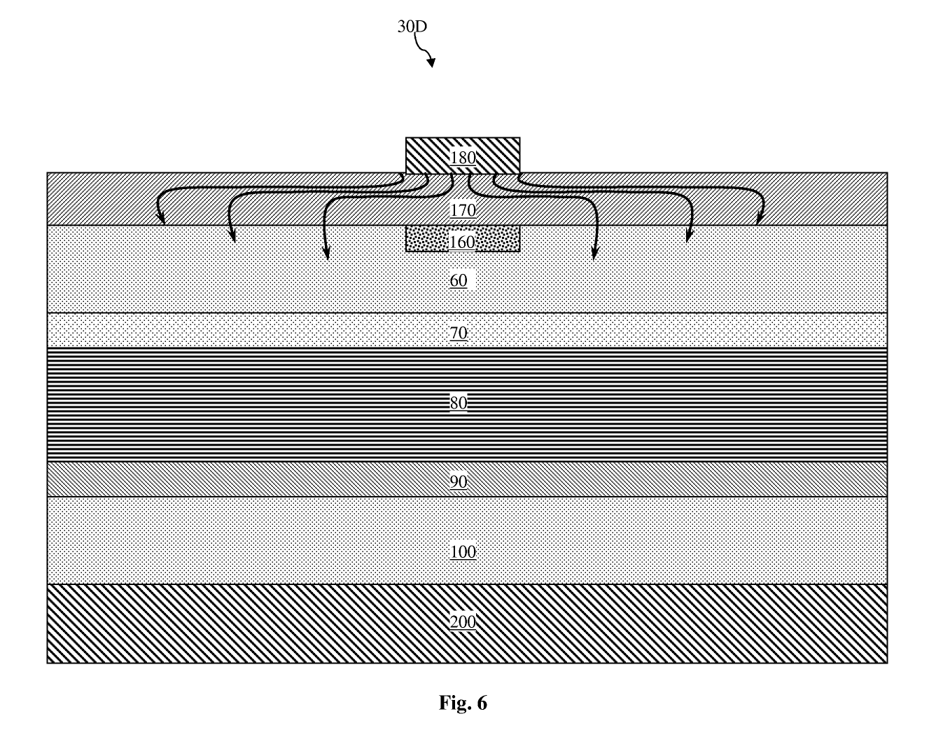

The LEDs 30A-30C illustrated in FIGS. 2-5 above pertain to a horizontal LED. The method of forming the embedded current blocking layer 160 for the LEDs 30A-30C may also be used to fabricate a vertical LED, the various embodiments of which are illustrated in FIGS. 6-11. Once again, similar components in the vertical and horizontal LEDs are labeled the same for reasons of consistency and clarity.

Referring to FIG. 6, a vertical LED 30D has a submount 200. The submount 200 contains a metal material in the illustrated embodiments. In other embodiments, the submount 200 may include a silicon material. The doped semiconductor layer 100 is disposed on the submount 200. In the embodiment shown, the doped semiconductor layer 100 includes p-doped gallium nitride (pGaN). The electron blocking layer 90 is disposed on the doped semiconductor layer 100. The MQW layer 80 is disposed on the electron blocking layer 90. The pre-strained layer 70 is disposed on the MQW layer 80. The doped semiconductor layer 60 is disposed on the pre-strained layer 70. In the embodiment shown, the doped semiconductor layer 60 includes n-doped gallium nitride (nGaN). The current blocking layer 160 is formed in the doped semiconductor layer 60. The contact layer 170 is disposed on the doped semiconductor layer 60 and over the current blocking layer 160. The metal contact 180 is disposed on the contact layer 170. Electrical access to the doped layers of the LED 30D can be gained through the metal component 180 and the submount 200.

The current blocking layer 160 is formed by an ion implantation process similar to the process 150 (or a thermal diffusion process) discussed above with reference to FIG. 2, with adjusted process parameters. Due to this method of formation (i.e., through implantation or thermal diffusion rather than deposition and lithography patterning), the current blocking layer 160 is embedded within the LED 30D and does not result in an uneven surface topography. Stated differently, the surface of the doped semiconductor layer 60 (containing the embedded current blocking layer 160) is substantially flat, so are the surfaces of the layers formed on the layer 60. As discussed above, current leakage and other defects can be substantially reduced due to the embedded current blocking layer 160.

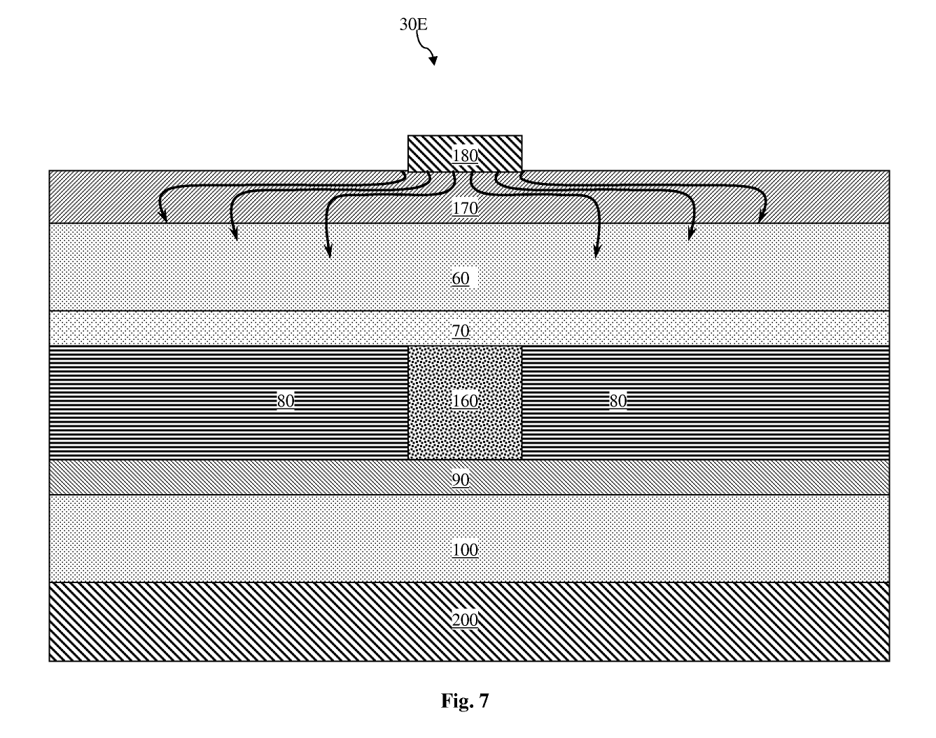

Referring to FIG. 7, a vertical LED 30E is substantially similar to the vertical LED 30D discussed above with reference to FIG. 6. Unlike the vertical LED 30D, however, the current blocking layer 160 is embedded in the MQW layer 80 for the LED 30E. The different embedded location of the current layer 160 in the LED 30E may be achieved by tuning one or more process parameters of the ion implantation process used to form it, for example implantation energy. Nevertheless, regardless of the location, the current blocking layer 160 can still divert current flow away from it, and its embedded nature reduces defects such as leakage current.

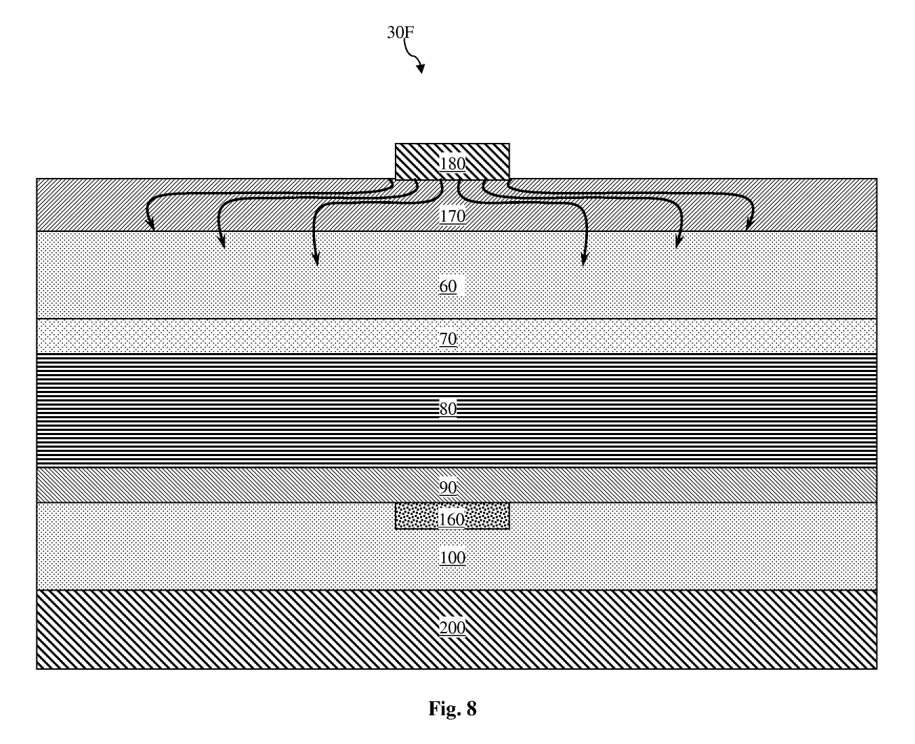

Referring to FIG. 8, a vertical LED 30F is substantially similar to the vertical LEDs 30D and 30E discussed above with reference to FIGS. 6-7. Unlike the vertical LEDs 30D-30E, however, the current blocking layer 160 is embedded in the doped semiconductor layer 100 for the LED 30F. The different embedded location of the current layer 160 in the LED 30F may be achieved by tuning one or more process parameters of the ion implantation process used to form it, for example implantation energy. Nevertheless, regardless of the location, the current blocking layer 160 can still divert current flow away from it, and its embedded nature reduces defects such as leakage current.

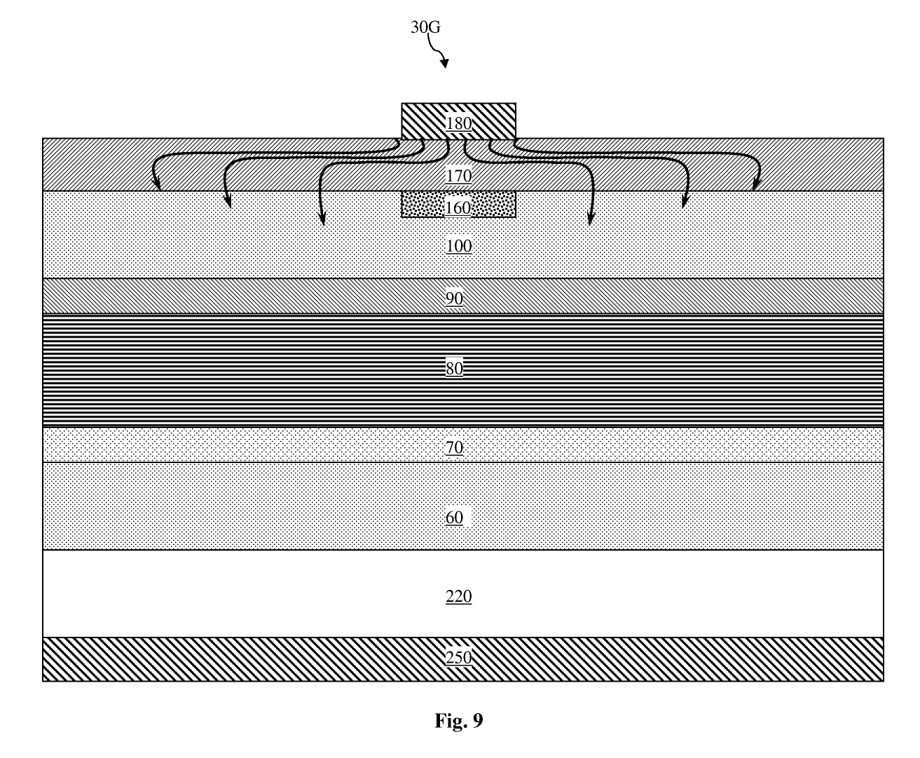

Referring to FIG. 9, another embodiment of a vertical LED 30G is illustrated. The LED 30G has a III-V compound substrate 220. In the illustrated embodiment, the substrate 220 includes n-doped gallium nitride. One side of the III-V compound substrate 220 is attached to a metal layer 250. The other side of the III-V compound substrate 220 is electrically coupled to the doped semiconductor layer 60. In the embodiment shown, the doped semiconductor layer 60 includes n-doped gallium nitride (nGaN). The pre-strained layer 70 is disposed on the doped semiconductor layer 60. The MQW layer 80 is disposed on the pre-strained layer 70. The electron blocking layer 90 is disposed on the MQW layer 80. The doped semiconductor layer 100 is disposed on the electron blocking layer 90. In the embodiment shown, the doped semiconductor layer 100 includes p-doped gallium nitride (pGaN). The current blocking layer 160 is formed in the doped semiconductor layer 100. The contact layer 170 is disposed on the doped semiconductor layer 100 and over the current blocking layer 160. The metal contact 180 is disposed on the contact layer 170. Electrical access to the doped layers of the LED 30G can be gained through the metal component 180 and the metal layer 250.

The current blocking layer 160 is formed by an ion implantation process similar to the process 150 (or a thermal diffusion process) discussed above with reference to FIG. 2, with adjusted process parameters. Due to this method of formation (i.e., through implantation or thermal diffusion rather than deposition and lithography patterning), the current blocking layer 160 is embedded within the LED 30E and does not result in an uneven surface topography. Stated differently, the surface of the doped semiconductor layer 100 (containing the embedded current blocking layer 160) is substantially flat, so are the surfaces of the layers formed on the layer 100. As discussed above, current leakage and other defects can be substantially reduced due to the embedded current blocking layer 160.

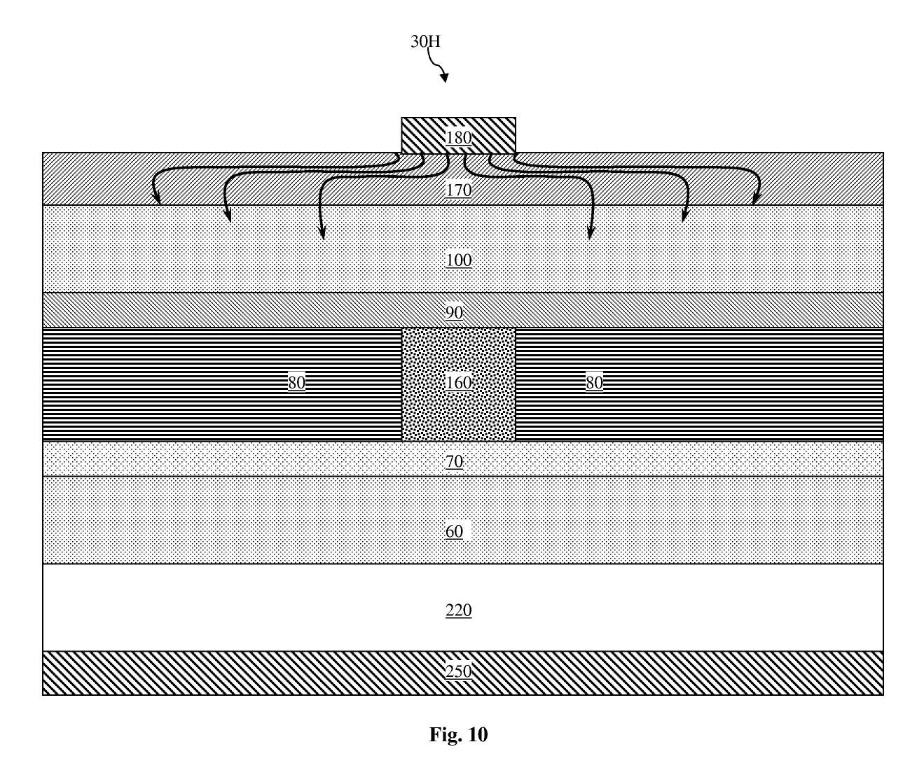

Referring to FIG. 10, a vertical LED 30H is substantially similar to the vertical LED 30G discussed above with reference to FIG. 9. Unlike the vertical LED 30G, however, the current blocking layer 160 is embedded in the MQW layer 80 for the LED 30H. The different embedded location of the current layer 160 in the LED 30H may be achieved by tuning one or more process parameters of the ion implantation process used to form it, for example implantation energy. Nevertheless, regardless of the location, the current blocking layer 160 can still divert current flow away from it, and its embedded nature reduces defects such as leakage current.

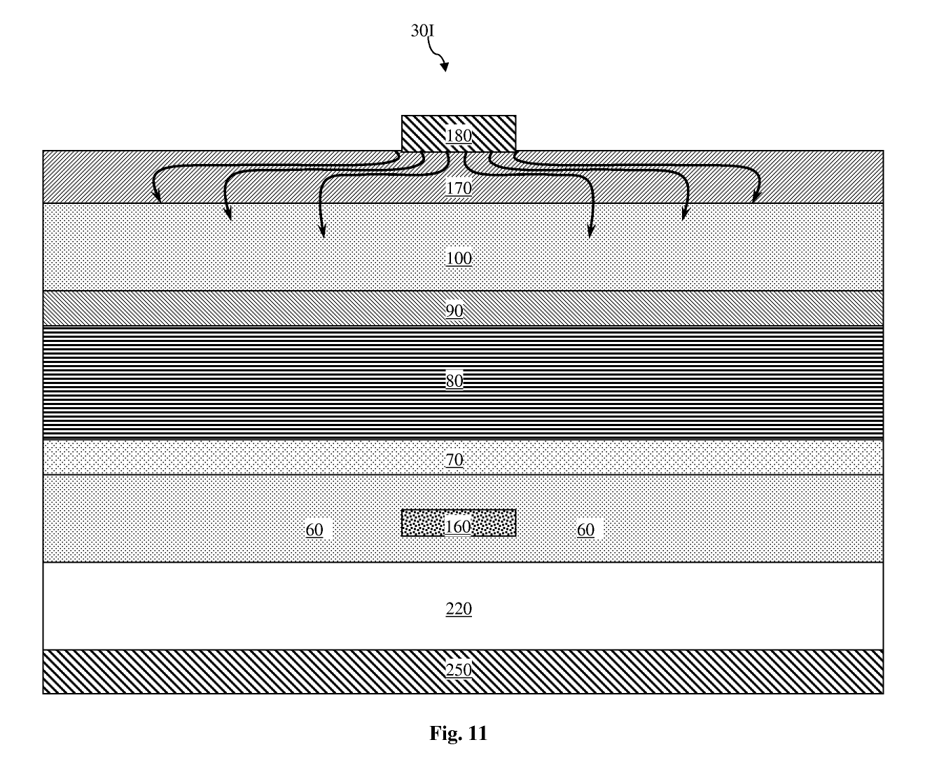

Referring to FIG. 11, a vertical LED 30I is substantially similar to the vertical LEDs 30G and 30H discussed above with reference to FIGS. 9-10. Unlike the vertical LEDs 30G-30H, however, the current blocking layer 160 is embedded in the doped semiconductor layer 60 for the LED 30I. The different embedded location of the current layer 160 in the LED 30I may be achieved by tuning one or more process parameters of the ion implantation process used to form it, for example implantation energy. Nevertheless, regardless of the location, the current blocking layer 160 can still divert current flow away from it, and its embedded nature reduces defects such as leakage current.

To complete the fabrication of the LEDs 30A-30I, additional processes such as dicing, packaging, and testing processes may also be performed, but they are not illustrated herein for the sake of simplicity.

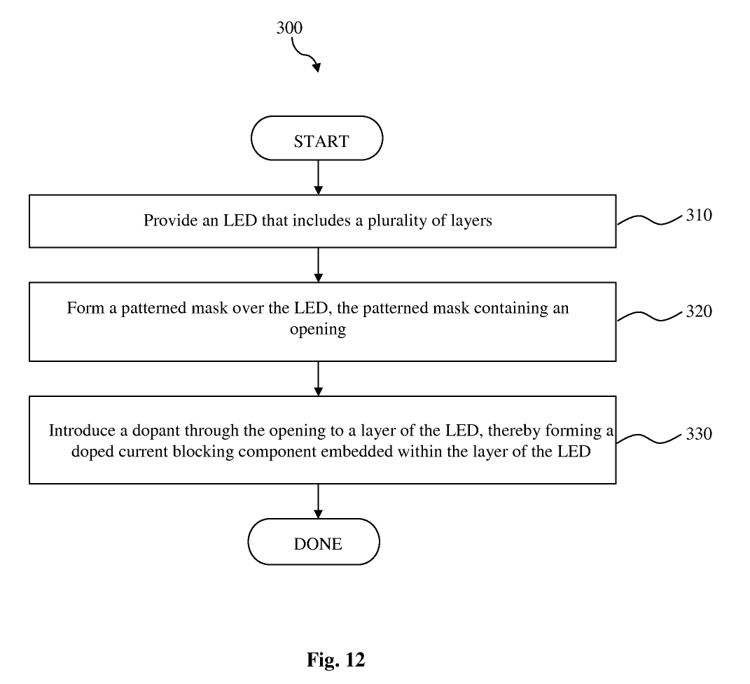

FIG. 12 is a flowchart of a method 300 for fabricating a photonic device according to various aspects of the present disclosure. Referring to FIG. 12, the method 300 includes a block 310, in which an LED is provided. The LED includes a plurality of layers. For example, the LED may include a p-doped gallium nitride layer and an n-doped gallium nitride layer, as well as a multiple quantum well (MQW) layer disposed between the p-doped and n-doped gallium nitride layers. In some embodiments, the LED is a horizontal LED having a sapphire substrate. In some other embodiments, the LED is a vertical LED having a gallium nitride substrate or a silicon submount or a metal submount.

The method 300 includes a block 320, in which a patterned mask is formed over the LED. The patterned mask may be a photoresist mask and contains an opening. The method includes a block 330, in which a dopant is introduced through the opening to a layer of the LED. The dopant may be introduced through either an ion implantation process or a thermal diffusion process. In some embodiments, the dopant includes ions such as Caesium ions, Argon ions, Neon ions, Krypton ions, Nitrogen ions, Aluminum ions, Oxygen ions, or Boron ions. In some embodiments, the implanting process in the block 330 is performed using a dose density in a range from about 1.0×10¹⁰ ions/centimeter² to about 1.0×10¹⁸ ions/centimeter². As a result of the dopant introduction process, a doped current blocking component is formed in the layer of the LED. In some embodiments, the layer in which the current blocking component is formed is the MQW layer, the p-doped gallium nitride layer, the n-doped gallium nitride layer, or the gallium nitride substrate in case the LED is a vertical LED having a gallium nitride substrate.

It is understood that additional processes may be performed before, during, or after the blocks 310-330 discussed herein to complete the fabrication of the photonic device. For example, in some embodiments, after the block 330 is executed, the patterned mask is removed. The LED may also annealed. Thereafter, a contact layer may be formed over the LED. A metal contact is also formed over the contact layer. The metal contact is approximately vertically aligned with the current blocking component. Other processes are not discussed in detail herein for reasons of simplicity.

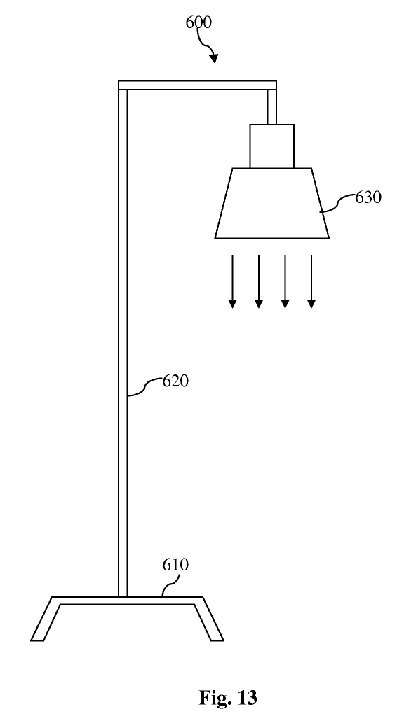

FIG. 13 illustrates a simplified diagrammatic view of a lighting module 600 that includes LEDs fabricated according to the various aspects of the present disclosure discussed above. The lighting module 600 has a base 610, a body 620 attached to the base 610, and a lamp 630 attached to the body 620. In some embodiments, the lamp 630 is a down lamp (or a down light lighting module). In other embodiments, the lamp 630 may be other suitable light fixtures. The lamp 630 uses LEDs discussed above with reference to FIGS. 1-12 as its light source. In other words, the LEDs of the lamp 630 of the lighting module 600 contain embedded current blocking layers, which lead to improved surface topography of the LEDs. Consequently, the LEDs have reduced defects such as current leakage or excessive operation voltage.

The LEDs discussed according to the embodiments disclosed herein offer advantages over existing LEDs. It is understood, however, that not all advantages are necessarily discussed herein, and different embodiments may offer additional advantages, and that no particular advantage is required for all embodiments.

One advantage is that since the current blocking layer is formed to be embedded within a layer of the LED, the LED would not suffer from an uneven surface topography. In traditional LEDs, the current blocking layer is typically formed by depositing a dielectric layer over a layer of the LED and patterning the dielectric layer to form the current blocking layer. The traditional method of forming the current blocking layer leads to an uneven LED layer surface, as the current blocking layer is disposed over or above the layer on which it is formed. This is likely to cause defects such as leakage current and/or excessively high operation voltage. In comparison, since the current blocking layer disclosed herein is formed by an implantation process or a thermal diffusion process, it is embedded within a given layer of the LED and therefore causes no adverse impact on the surface topography of the LED. Consequently, defects such as current leakage and/or high operation voltage can be substantially reduced or eliminated.

Another advantage is that since the current blocking layer is formed using an ion implantation method or a thermal diffusion method, rather than a deposition/lithography patterning method, the LED disclosed herein entails a simpler fabrication process. In other words, the LED disclosed herein requires fewer fabrication tools (i.e., no deposition tools or lithography tools are required), and the implantation process or the thermal diffusion process can be performed more quickly than depositing a dielectric layer and patterning the dielectric layer. In addition, the implementation of the current blocking layer disclosed herein is compatible with current LED fabrication processes.

One of the broader forms of the present disclosure involves a lighting apparatus. The lighting apparatus includes a photonic die structure that includes a plurality of layers, wherein a current blocking layer is embedded in one of the plurality of layers. The current blocking layer is a doped layer.

In some embodiments, the photonic die structure includes a multiple quantum well (MQW) layer disposed between a p-doped III-V group compound layer and an n-doped III-V group compound layer.

In some embodiments, the current blocking layer is embedded within one of: the MQW layer, the p-doped III-V compound layer, and the n-doped III-V compound layer.

In some embodiments, the layer in which the current blocking layer is embedded has a flat surface.

In some embodiments, the doped layer may include a dopant that is Caesium, Argon, Neon, Krypton, Nitrogen, Aluminum, Oxygen, or Boron.

In some embodiments, the photonic die structure includes a metal contact; and the current blocking layer is aligned with the metal contact.

In some embodiments, the photonic die structure includes one of: a horizontal light-emitting diode (LED) and a vertical LED.

Another one of the broader forms of the present disclosure involves an LED. The LED includes: a substrate; a p-doped III-V compound layer and an n-doped III-V compound layer each disposed over the substrate; a multiple quantum well (MQW) layer disposed between the p-doped III-V compound layer and the n-doped III-V compound layer; and a current blocking layer embedded in one of: the p-doped III-V compound layer, the n-doped III-V compound layer, the MQW layer, and the substrate. The current blocking layer includes a doped feature containing a dopant.

In some embodiments, the dopant may be Caesium, Argon, Neon, Krypton, Nitrogen, Aluminum, Oxygen, or Boron.

In some embodiments, the layer in which the current blocking layer is embedded has a substantially even-surfaced topography.

In some embodiments, the LED further includes a metal contact component substantially vertically aligned with the current blocking layer.

In some embodiments, the LED is a horizontal LED and the substrate is a sapphire substrate.

In some embodiments, the LED is a vertical LED and the substrate is a gallium nitride substrate, a silicon submount, or a metal submount.

Yet another one of the broader forms of the present disclosure involves a method of fabricating an LED. The method includes: providing an LED that includes a plurality of layers; forming a patterned mask over the LED, the patterned mask containing an opening; and introducing a dopant through the opening to a layer of the LED, thereby forming a doped current blocking component embedded within the layer of the LED.

In some embodiments, the dopant ions are Caesium, Argon, Neon, Krypton, Nitrogen, Aluminum, Oxygen, or Boron.

In some embodiments, the dopant is introduced through an ion implantation process, and the ion implantation process is performed with a dose density in a range from about 1.0×10¹⁰ ions/centimeter² to about 1.0×10¹⁸ ions/centimeter².

In some embodiments, the dopant is introduced through a thermal diffusion process.

In some embodiments, the method further includes: removing the patterned mask; annealing the LED; forming a contact layer over the LED; and forming a metal contact over the contact layer, wherein the metal contact is approximately vertically aligned with the current blocking component.

In some embodiments, the LED includes a multiple quantum well (MQW) layer disposed between a p-doped gallium nitride layer and an n-doped gallium nitride layer; and the current blocking component is embedded within one of: the MQW layer, the p-doped gallium nitride layer, and the n-doped gallium nitride layer.

In some embodiments, the LED includes a horizontal LED or a vertical LED.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An apparatus, comprising:
a photonic die structure that includes a plurality of layers, wherein a current blocking layer is embedded in one of the plurality of layers, and wherein the current blocking layer is a doped layer.

2. The apparatus of claim 1, wherein the photonic die structure includes a multiple quantum well (MQW) layer disposed between a p-doped III-V group compound layer and an n-doped III-V group compound layer.

3. The apparatus of claim 2, wherein the current blocking layer is embedded within one of: the MQW layer, the p-doped III-V compound layer, and the n-doped III-V compound layer.

4. The apparatus of claim 1, wherein the layer in which the current blocking layer is embedded has a flat surface.

5. The apparatus of claim 1, wherein the current blocking layer contains a dopant selected from the group consisting of: Caesium, Argon, Neon, Krypton, Nitrogen, Aluminum, Oxygen, and Boron.

6. The apparatus of claim 1, wherein:
the photonic die structure includes a metal contact; and
the current blocking layer is aligned with the metal contact.

7. The apparatus of claim 1, wherein the photonic die structure includes one of: a horizontal light-emitting diode (LED) and a vertical LED.

8. The apparatus of claim 1, further comprising: a lighting module in which the photonic die is implemented.

9. A light-emitting diode (LED), comprising:
a substrate;
a p-doped III-V compound layer and an n-doped III-V compound layer each disposed over the substrate;
a multiple quantum well (MQW) layer disposed between the p-doped III-V compound layer and the n-doped III-V compound layer; and
a current blocking layer embedded in one of: the p-doped III-V compound layer, the n-doped III-V compound layer, the MQW layer, and the substrate, wherein the current blocking layer include a doped feature containing a dopant.

10. The LED of claim 9, wherein the dopant is selected from the group consisting of: Caesium, Argon, Neon, Krypton, Nitrogen, Aluminum, Oxygen, and Boron.

11. The LED of claim 9, wherein the layer in which the current blocking layer is embedded has a substantially even-surfaced topography.

12. The LED of claim 9, further comprising: a metal contact component substantially vertically aligned with the current blocking layer.

13. The LED of claim 9, wherein the LED is a horizontal LED and the substrate is a sapphire substrate.

14. The LED of claim 9, wherein the LED is a vertical LED and the substrate is a gallium nitride substrate, a silicon submount, or a metal submount.

15. A method of fabricating a light-emitting diode (LED), comprising:
providing an LED that includes a plurality of layers;
forming a patterned mask over the LED, the patterned mask containing an opening; and
introducing a dopant through the opening to a layer of the LED, thereby forming a doped current blocking component embedded within the layer of the LED.

16. The method of claim 15, wherein:
the dopant is selected from the group consisting of: Caesium, Argon, Neon, Krypton, Nitrogen, Aluminum, Oxygen, and Boron.

17. The method of claim 15, wherein the dopant is introduced through an ion implantation process, and wherein the ion implantation process is performed with a dose density in a range from about 1.0×10¹⁰ ions/centimeter² to about 1.0×10¹⁸ ions/centimeter².

18. The method of claim 15, wherein the dopant is introduced through a thermal diffusion process.

19. The method of claim 15, further comprising, after the introducing:
removing the patterned mask;
annealing the LED;
forming a contact layer over the LED; and
forming a metal contact over the contact layer, wherein the metal contact is approximately vertically aligned with the current blocking component.

20. The method of claim 15, wherein:
the LED includes a multiple quantum well (MQW) layer disposed between a p-doped gallium nitride layer and an n-doped gallium nitride layer; and
the current blocking component is embedded within one of: the MQW layer, the p-doped gallium nitride layer, and the n-doped gallium nitride layer.
